(19) United States
(12) Patent Application Publication
(10) Pub. No.: US 2026/0202139 A1
(43) Pub. Date: Jul. 16, 2026

(54) Integrated Thermal Ground Plane

(71) Applicant: Kelvin Thermal Technologies, Inc., Boulder, CO (US)

(72) Inventors: Ryan Lewis, Boulder, CO (US); Hunter Anderson, Boulder, CO (US); Kai Min Teh, Boulder, CO (US); James Smith, Boulder, CO (US); Brooke James, Boulder, CO (US); Cheng Chen Cheng, Boulder, CO (US); Chin Jen Huang, Boulder, CO (US); Yung-Cheng Lee, Boulder, CO (US)

(73) Assignee: Kelvin Thermal Technologies, Inc., Boulder, CO (US)

(21) Appl. No.: 19/545,002

(22) Filed: Feb. 19, 2026

Related U.S. Application Data
(63) Continuation-in-part of application No. 18/779,455, filed on Jul. 22, 2024.
(60) Provisional application No. 63/515,013, filed on Jul. 21, 2023.

(51) Int. Cl. F28D 15/02; F28D 15/04; H05K 7/20

(52) U.S. Cl. CPC F28D 15/0266; F28D 15/046; H05K 7/20336

(57) ABSTRACT

A thermal ground plane is disclosed that may comprise a first casing and a second casing. The outer periphery of the first casing and the outer periphery of the second casing may be bonded to each other with a hermetic seal and to create an internal cavity. A first wick may be bonded with the first casing. A second wick may be disposed within the internal cavity. The second wick may be bonded with the second casing. The liquid feed structure may be disposed between the first wick and the second wick. The liquid feed structure may allow liquid transport between the first wick and the second wick. The liquid feed structure may comprise a plurality of individual feed strips. A working fluid may be disposed within the internal cavity. The second casing, for example, may be shared with a cold plate or a heat sink.

### CROSS REFERENCE TO RELATED APPLICATIONS

This application is a continuation-in-part of U.S. patent application Ser. No. 18/779,455, filed on Jul. 22, 2024, which claims priority to U.S. provisional patent application Ser. No. 63/515,013, filed Jul. 21, 2024, the entire disclosure of both of these are hereby incorporated by reference.

### BACKGROUND

A thermal ground plane, also known as a vapor chamber, may provide a passive thermal management solution by enclosed microfluid systems. An advanced thermal ground plane may include a mesh wick permeated by some liquid. When heat is applied to the system, the liquid evaporates and generates a warm vapor within a vapor channel. The warm vapor has elevated pressure due to saturation pressure effect, and the elevated pressure causes internal convection currents in the vapor phase. That convection carries heat throughout the vapor phase, until the temperature is nearly uniform. The vapor condenses in cooler regions, and the condensed liquid is pulled back through the wick to the heat source by capillary forces resulting from the wick. A thermal ground plane, therefore, is able to spread heat. By using phase change and internal convection, a thermal ground plane can have effective conductivity much higher than solid heat spreaders such as copper or graphite.

### SUMMARY

Thermal ground planes are disclosed that can be used in various applications such as, for example, high power electronics in data centers for artificial intelligence (AI) and edge computing for robots.

A thermal ground plane is disclosed that includes a first casing that is substantially planar and a second casing. The outer periphery of the first casing and the outer periphery of the second casing are bonded together to form a hermetic seal. The second casing may be deformed to create a vapor support structure within the thermal ground plane that includes a plurality of deformed portions (or rough pillars). A working fluid may be disposed within the internal cavity. A permeable wick may also be disposed on inner surfaces of the first casing and/or second casing for liquid transport that is disposed between the first casing and the second casing.

In one example of the thermal ground plane described above, the first casing and/or the second casing comprises at least one of copper, aluminum, and stainless steel. In one example of the thermal ground plane described above, the first casing and/or the second casing comprises a flexible laminate having a plurality of layers where at least one of the plurality of layers comprises polymer.

In one example of the thermal ground plane described above, the liquid feed structure may include a plurality of mesh layers that may be connecting wicks attached to the first casing and the second casing.

As another example, the liquid feed structure can have a shape selected from the group consisting of a wavy shape, a triangular shape, a trapezoid shape, and an asymmetric wave shape.

In one example of the thermal ground plane described above, a vapor support structure disposed may be included between the first casing and the second casing. The vapor support structure and the liquid feed structure, for example, may be disposed in the space within the thermal ground plane.

In one example of the thermal ground plane described above, the second wick includes a plurality of mesh layers. The plurality of mesh layers, for example, may include at least a first mesh layer and a second mesh layer, the first mesh layer has a pore size greater than the pore size of the second mesh layer, and the first mesh layer is disposed between the second casing and the second mesh layer.

In one example of the thermal ground plane described above, the first wick includes a plurality of mesh layers. The plurality of mesh layers, for example, include at least a first mesh layer and a second mesh layer, the first mesh layer has a pore size greater than the pore size of the second mesh layer, and the second mesh layer is disposed between the first casing and the first mesh layer. The periphery of the plurality of mesh layers, for example, can be flattened for reduced pore size small enough to prevent vapor penetration into the liquid transport channel.

In one example of the thermal ground plane described above is integrated with a cold plate having cooling liquid flowing through. The second casing for condensation heat transfer is shared with the cold plate. The second casing may comprise copper, stainless steel, polymer layer, or any combination thereof.

In one example of the thermal ground plane described above is integrated with a plurality of cold tubes having cooling liquid flowing through. These tubes are embedded in the vapor transport space serving as condenser.

In one example of the thermal ground plane described above is integrated with an air-cooled heat sink. The second casing may be corrugated to form an array of fins or be coupled with an array of fins.

In one example of the thermal ground plane described above is integrated with a cold plate having cooling liquid flowing through. The thermal ground plane and cold plate are folded into a three-dimensional configuration.

In one example of the thermal ground plane described above is integrated with cold plates having cooling liquid flowing through. The thermal ground plane is folded with a plurality of cold plates attached to regions of thermal ground plane's first and second casings through thermal interface materials.

In another example, a thermal ground plane may comprise a first casing. A first wick may be bonded with the first casing. The first wick may be configured for liquid transport associated with evaporation or boiling. A second casing may be included. The outer periphery of the first casing and the outer periphery of the second casing may be bonded to each other with a hermetic seal. The bonded peripheries may form an internal cavity. A second wick may be disposed within the internal cavity. The second wick may be bonded with the second casing. The second wick may be configured for liquid transport associated with condensation. A liquid feed structure may be disposed within the internal cavity. The liquid feed structure may be disposed between the first wick and the second wick. The liquid feed structure may allow liquid transport between the first wick and the second wick. The liquid feed structure may comprise a plurality of individual feed strips. A space may be present between adjacent individual feed strips. Each of the plurality of individual feed strips may be coupled with a tie-bar. A working fluid may be disposed within the internal cavity.

For example, each of the plurality of individual feed strips may comprise a wavy structure. The wavy structure of adjacent individual feed strips may be offset by about half a wavelength relative to one another. The liquid feed structure may comprise one or more mesh. The space between adjacent individual feed strips may be less than about 1.5 mm. Either or both the first wick and/or the second wick may comprise a mesh coated with a layer of microparticles. The layer of microparticles may comprise a thickness less than one and a half the diameter of the average microparticle. More than 90% of the layer of microparticles may comprise a single layer of microparticles. The plurality of microparticles may have an average diameter less than about 5 microns.

As another example, a thermal ground plane may comprise a first casing. A second casing may be included. The outer periphery of the first casing and the outer periphery of the second casing may be bonded to each other with a hermetic seal. The bonded peripheries may form an internal cavity. A first wick may be disposed within the internal cavity. The first wick may be bonded with the first casing. The first wick may be configured for liquid transport associated with evaporation or boiling. A second wick may be disposed within the internal cavity. The second wick may be bonded with the second casing. The second wick may be configured for liquid transport associated with condensation. A working fluid may be disposed within the internal cavity. A liquid-cooled cold plate may be included. The second casing may be part of the liquid-cooled cold plate.

For example, liquid may flow through the liquid-cooled cold plate. The liquid may be in contact with a portion of the second casing. There may be no thermal interface material disposed between the liquid-cooled cold plate and the second casing. The liquid-cooled cold plate may comprise a third casing. The outer periphery of the second casing may be bonded with an outer periphery of the third casing. The bonding may form a hermetic seal. The hermetic seal may allow liquid to flow between the second casing and the third casing. The second casing may comprise a plurality of layers including a polymer layer. The liquid-cooled cold plate may be folded.

As another example, a thermal ground plane may comprise a first casing. A second casing may comprise a plurality of fins. The plurality of fins may extend out of plane from an external surface of the second casing. The outer periphery of the first casing and the outer periphery of the second casing may be bonded to each other with a hermetic seal. The bonded peripheries may form an internal cavity. A first wick may be disposed within the internal cavity. The first wick may be bonded with the first casing. The first wick may be configured for liquid transport associated with evaporation or boiling. A second wick may be disposed within the internal cavity. The second wick may be bonded with the second casing. The second wick may be configured for liquid transport associated with condensation. A working fluid may be disposed within the internal cavity.

The second wick, for example, may extend into at least a subset of the plurality of the fins. As another example, the second wick may extend into the cavity and increase the surface area for enhanced condensation.

As another example, a cooling system may comprise a first cold plate. The first cold plate may have a first physical shape. The first cold plate may have a liquid-cooling channel. A thermal ground plane may have a second physical shape. The thermal ground plane may be folded around portions of the cold plate. The thermal ground plane may substantially conform to a portion of the first physical shape. The thermal ground plane may comprise a first casing. The first casing may have a shape that substantially conforms with the second physical shape. A second casing may have a shape that substantially conforms with the second physical shape. The second casing may be in contact with two or more surfaces of the first cold plate. The outer periphery of the first casing and the outer periphery of the second casing may be bonded to each other with a hermetic seal. The bonded peripheries may form an internal cavity. A first wick may be configured for liquid transport associated with evaporation or boiling. The first wick may be disposed within the internal cavity. The first wick may be bonded with the first casing. The first wick may be folded to conform. A second wick may be configured for liquid transport associated with both condensation and evaporation. The second wick may be disposed within the internal cavity. The second wick may be bonded with the second casing. A working fluid may be disposed within the internal cavity.

For example, the internal cavity may be maintained through folds of the thermal ground plane. The first wick may have a shape that substantially conforms with the second physical shape. The second wick may have a shape that substantially conforms with the second physical shape. A second cold plate may be included. The second cold plate may have liquid-cooling channels. The first wick may be configured for liquid transport associated with condensation. The first casing may be in contact with two or more surfaces of the second cold plate. A third cold plate may be included. The third cold plate may have liquid-cooling channels. The second casing may be in contact with one or more surfaces of the third cold plate. The second casing may comprise a polymer layer.

### BRIEF DESCRIPTION OF THE FIGURES

FIG. 1A is a cutaway side view illustration of an example internal structure of a thermal ground plane.

FIG. 1B is an example plane view illustration of a mesh.

FIG. 2A is a cutaway side view illustration of an example internal structure of a thermal ground plane.

FIG. 2B is a cutaway top view illustration of an example internal structure of the thermal ground plane shown in FIG. 2A.

FIG. 3 is an example illustration of a liquid feed structure.

FIG. 4A is an illustration of an example sideview of a condensation wick.

FIG. 4B is an illustration of an example sideview of a condensation wick.

FIG. 5 is an example illustration of a sideview of a multilayer mesh.

FIG. 6 is a cutaway side view illustration of an example internal structure of a thermal ground plane that includes two types of vapor support structures.

FIG. 7A and FIG. 7B are side view and top view illustrations of an example copper mesh coated with microparticles.

FIG. 8 is a cutaway side view illustration of an example internal structure of an integrated thermal ground plane with a cold plate.

FIG. 9A and FIG. 9B are cutaway side view and top view illustrations of an example internal structure of a thermal ground plane with cooling pipes serving as the condenser.

FIG. 10 is a cutaway side view illustration of an example internal structure of a thermal ground plane with fins.

FIG. 11A and FIG. 11B are plane and sideview illustrations of an example folded thermal ground plane integrated with multiple cold plates or heat sinks.

### DETAILED DESCRIPTION

Three-dimensional meshes and casings for advanced thermal ground planes, among other things, are disclosed. A thermal ground plane, also known as a vapor chamber, is a passive thermal management solution with enclosed microfluid systems. A thermal ground plane typically includes a wick permeated by some liquid. When heat is applied to the system, the liquid evaporates and generates a warm vapor within a vapor cavity. The warm vapor has elevated pressure due to saturation pressure effect, which causes internal convection currents in the vapor phase. This convection carries heat throughout the vapor phase, until the temperature is nearly uniform. The vapor condenses in cooler regions, and the condensed liquid is pulled back through the wick to the heat source by capillary forces resulting from the wick. A thermal ground plane, therefore, may be able to spread heat. By using phase change and internal convection, a thermal ground plane can have effective conductivity much higher than solid heat spreaders such as copper or graphite.

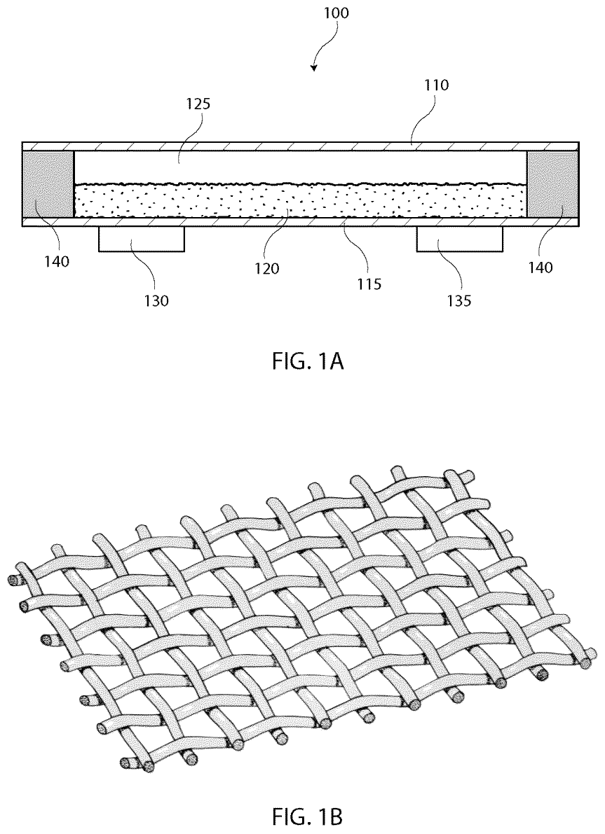

The elements of a thermal ground plane are the outer casing, wick structure, vapor space, and encapsulated fluid, as in FIG. 1. Meshes are used as wicks in most of thermal ground planes. To meet challenging requirements of new applications of thermal ground planes, improvements to the meshes and casings can be useful. A major improvement is to apply three-dimensional configurations that can offer the features well beyond what two-dimensional can achieve.

The examples of thermal ground planes described in this document and shown in any of the figures are not drawn to scale and features may be out of proportion relative to other features. Some features shown in the figures may be exaggerated for illustration purposes.

FIG. 1A is a cutaway side view illustration of an example internal structure of a thermal ground plane 100. In this example, the thermal ground plane 100 includes a condenser casing 110 (or second casing) and an evaporator casing 115 (or first casing) that are sealed together to create an internal cavity. A wick 120 (or liquid structure), and/or a vapor structure 125 may be disposed within the internal cavity. The thermal ground plane 100, for example, may operate with evaporation, vapor transport, condensation, and liquid return of water or other cooling media for heat transfer between the evaporation region 130 and the condensation region 135. The structures and/or characteristics of the thermal ground plane 100 may be applied to any embodiment or example described within this document.

The condenser casing 110, for example, may include copper, stainless steel, aluminum, polymer, atomic layer deposition (ALD) coated polymer, flexible copper clad laminate (FCCL), polymer-coated copper, copper-cladded Kapton, etc. The evaporator casing 115, for example, may include copper, stainless steel, aluminum, polymer, ALD coated polymer, FCCL, polymer-coated copper, copper-cladded Kapton, etc. The condenser casing 110 and the evaporator casing 115, for example, may be sealed together using solder, laser welding, ultrasonic welding, electrostatic welding, or thermocompression bonding (e.g., diffusion bonding) or a sealant. The condenser casing 110 and the evaporator casing 115, for example, may include the same or different materials.

The condenser casing 110 and/or the evaporator casing 115, for example, may comprise a flexible copper clad laminate with at least three layers: a first layer of copper (e.g., 12 microns thick), a second layer of polyimide (e.g., 12 microns thick), and a third layer of copper (e.g., 12 microns thick). Each of these three layers may have a thickness of or less than 50, 20, 15, 12, 10, 8 microns. The polyimide, for example, may be sandwiched between two copper layers. The copper layers on the condenser casing and/or the evaporator casing, for example, can be replaced with ALD nano-scaled layers such as, for example, Al₂O₃, TiO₂, SiO₂, for extremely thin casings (e.g., with a thickness less than about 10 microns).

The evaporation region 130 and the condensation region 135 may both be disposed on the condenser casing 110 or on the evaporator casing 115. Alternatively, the evaporation region 130 and the condensation region 135 may be disposed on different layers of the condenser casing 110 and the evaporator casing 115.

In some embodiments, the outer periphery of the condenser casing 110 and the outer periphery of the evaporator casing 115 may be sealed at bonded perimeter 140 such as, for example, hermetically sealed using any number of techniques.

Various examples described in this disclosure include a mesh. FIG. 1B is an example of a mesh that is woven. The term mesh as used throughout this disclosure may, in some examples, include a mesh with a structure similar to what shown in FIG. 1B where a plurality of threads are woven together to create material with a plurality of pores. Various other types of mesh may also be used.

A mesh, for example, may comprise copper and/or stainless steel. A mesh, for example, may include a material having pores that have a dimension of about 10 to about 200 μm. A nonporous mesh, for example, may include a material that may have pores that a have a dimension of about 0.2 to 10 μm. A mesh may be characterized by a pore size and/or a mesh number. The pore size indicates the average size of the pores within the mesh. For example, the average pore size of the pores in a mesh may be about 0.05 mm. The mesh number indicates the average number of threads or openings per inch. For example, a mesh with a mesh number #400 has 400 threads or openings per inch.

A mesh, for example, may include a material that includes either or both metal and polymer. A deformed wavy mesh, for example, may be highly stretchable, such as, for example, stretchable without plastic deformation, which may, for example, reduce the stress when folded and/or may prevent the formation of wrinkles and blocking of vapor flow. A mesh, for example, may be electrically conductive and/or may be coated in a dielectric material such as, for example, to prevent plating of material into the pores away from the anchors. The pores in a mesh, for example, may be made from polymer, ceramic, other electrically insulating materials or electrically conductive material and/or may be covered by an electrically insulating layer. A mesh, for example, may include a plurality of woven wires, non-woven wires, or porous planar media. A mesh, for example, may include an ALD-coated polymer without any metal. The ALD coating can be replaced with other thin film coatings. A mesh, for example, may include a copper-clad-polyimide laminate material. A mesh, for example, may include a copper mesh or non-copper mesh such as, for example, a polymer mesh or a stainless steel mesh. A mesh, for example, may be encapsulated by hydrophilic and anti-corrosion hermetic seal. A mesh, for example, may include any woven or nonwoven material. A mesh, for example, may include a plurality of layers of woven or nonwoven material.

A mesh, for example, may have a thickness of about 10 μm to about 1,000 μm. A woven mesh, for example, may have a thickness of about 1,000, 500, 125, 100, 75, 50, or 25 μm. A porous mesh (e.g., a nanoporous mesh and/or a non-woven mesh) may have a thickness of about 5, 10, 15, 20, or 25 μm. A mesh, for example, may include a metal foam.

Various thermal ground planes described in this disclosure may include an array of pillars, which may include any or all of the following. An array of pillars, for example, may include a plurality of pillars with an evenly or unevenly distributed pattern. An array of pillars, for example, may include pillars comprising polymer. An array of pillars, for example, may include pillars comprising metal such as, for example, copper or stainless steel. An array of pillars, for example, may include pillars coated with a coating such as, for example, a ceramic (e.g. Al₂O₃, TiO₂, SiO₂, etc.) or a nano-texture coating. The coating may be applied via defect-free ALD, low-defect density ALD, chemical vapor deposition (CVD), molecular layer deposition (MLD), or other nano-scaled or micro-scaled coating processes.

An array of pillars, for example, may be a pseudo-rectangular array, or a pseudo hexagonal array, or a random array. An array of pillars, for example, may have a center-to-center pitch that is constant across array of pillars. An array of pillars, for example, may include pillars with variable diameters and/or heights. An array of pillars, for example, may have a low density (e.g., far apart) at the condenser, have a higher density at the evaporator, and/or gradual change in density between the condenser and the evaporator.

Various examples described in this disclosure include a micro pillar array. For example, a micro pillar array may be disposed on an array of pillars, where the array of pillars are larger than the micro pillar array. A micro pillar array, for example, may include a deformed mesh or a porous material in which the pore size of the material is substantially smaller than the gap between pillars. A micro pillar array may, for example, include nano-wire bundles, sintered particles, templated grown pillars, inverse opals, etc. A micro pillar, for example, array may include solid pillars, which may promote conduction of heat along the length, and outer regions of the micropillar array may be porous to promote wicking.

Various examples described in this disclosure may include internal thermal ground plane structures comprising polymer. These thermal ground plane structures, for example, may include the condenser casing, the evaporator casing, a mesh, an array of pillars, arteries, wick, vapor structures, etc. Polymer structures, for example, may be coated with metal, defect-free ALD, low-defect density ALD, CVD, MLD, or other nano-scaled coating processes.

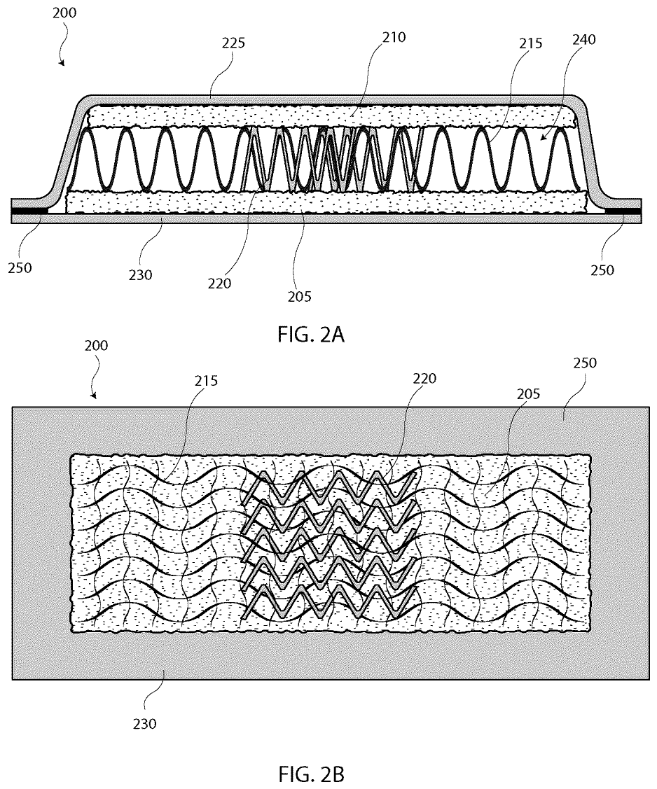

FIG. 2A is a cutaway side view illustration of an example internal structure of a thermal ground plane 200. And FIG. 2B is a cutaway top view illustration of an example internal structure of the thermal ground plane 200. The thermal ground plane 200 may, for example, be used in high power and high heat flux applications. In this example, the evaporator casing 230 (or first casing) may be substantially planar and/or flat. The condenser casing 225 (or second casing) and the evaporator casing 230 may be sealed around the periphery of the condenser casing 225 and the periphery of the evaporator casing 230. The evaporator casing 230 and the condenser casing 225 may form an internal cavity 240 within which various components may be disposed. A working fluid may be placed within the internal cavity 240.

The thermal ground plane 200 may be shown as being substantially planar or flat and/or may be made from substantially planar or flat components (e.g., casings, wicks, meshes, etc.), the thermal ground plane 200 may be folded or molded to fit around, fit with, conform to, or adapt to other components such as, for example, cold plates, silicon chips, etc.

The condenser casing 225, for example, may have a thickness of about 0.025 mm, 0.05 mm, 0.10 mm, 0.25 mm, 0.5 mm. As another example, the condenser casing 225 may have a thickness in the range of about 0.01 mm to about 2 mm. As another example, the condenser casing 225 may have a thickness greater than about 2 mm. As another example, the condenser casing 225 may have thickness exceeding, equal to, or less than about 1 cm.

The condenser casing 225, for example, may have a nonuniform thickness.

The condenser casing 225, for example, may have a length and/or a width of about 50 mm, 75 mm, 150 mm, 250 mm. As another example, the condenser casing 225 may have a length and/or a width between about 20 mm and about 500 mm. As another example, the condenser casing 225 may have a length and/or a width greater than about 500 mm.

The condenser casing 225, for example, may have a rectangular or a circular shape or any arbitrary shape.

The evaporator casing 230 may have the same size, shape, thickness, or dimension attributes as the condenser casing 225.

The condenser casing 225, for example, may include a single layer of material that has high thermal conductivity. The condenser casing 225, for example, may comprise copper, aluminum, stainless steel, silicon, ceramic, AlN, BeO, etc. The condenser casing 225, for example, may include a material that has a thermal conductivity greater than about 200 W/m/k. As another example, the condenser casing 225 can include a laminate comprising copper, polymer, and copper. With such a laminate casing, thermal vias through the polymer layer can be used to reduce thermal resistance. A cooling unit, e.g. liquid cooled cold plate, for example, can be attached to the inner copper layer through an opening of the polymer layer.

The evaporator casing 230, for example, may include a single layer of material that has high thermal conductivity. The evaporator casing 230, for example, may comprise copper, aluminum, stainless steel, silicon, ceramic, AlN, BeO, etc. The evaporator casing 230, for example, may include a material that has a thermal conductivity greater than about 200 W/m/k. As another example, the evaporator casing 230 can include a laminate comprising copper, polymer, and copper. With such a laminate casing, thermal vias through the polymer layer can be used to reduce thermal resistance. An electronic device, for example, can be attached to the inner copper layer through an opening of the polymer layer.

An evaporation wick 205 (e.g., boiling wick or evaporation/boiling wick or first wick) and/or a condensation wick 210 (e.g., second wick) may be disposed within the thermal ground plane 200. The evaporation wick 205 may be coupled or bonded with an inner surface of the evaporator casing 230 and/or the condensation wick 210 may be coupled or bonded with an inner surface of the condenser casing 225.

Various examples of components, materials features, and/or configurations for an evaporation wick 205 are disclosed. Each of these examples are designed for liquid transport associated with evaporation or boiling.

Various examples of components, materials features, and/or configurations for a condensation wick 210 are disclosed. Each of these examples are designed for liquid transport associated with condensation.

An evaporation wick 205 (or boiling wick), for example, may extend across substantially all the internal surface area of the evaporator casing 230. As another example, the evaporation wick 205 may extend across portions of the internal surface area of the evaporator casing 230. As another example, either or both the evaporation wick 205 and/or the condensation wick 210 may extend into the bonded perimeter 250.

The evaporation wick 205, for example, may have a thickness of about 0.01 mm to about 1.0 cm. The thickness of the evaporation wick 205, for example, may be nonuniform such that the thickness may vary from about 0.01 mm to about 1.0 cm. The thickness of the evaporation wick 205, for example, may be such that it fills substantially all, a substantially all of, or portions of the internal cavity formed between the evaporator casing 230 and the condenser casing 225 other than a liquid feed structure 220, if present, the condensation wick 210, and/or the plurality of support structures 215 if present. The thickness of the evaporation wick 205, for example, may be such that it is in contact with substantially all or portions of the top surface of the condensation wick 210.

The condensation wick 210, for example, may extend across the substantially all the internal surface area of the evaporator casing 230. As another example, the condensation wick 210 may extend across portions of the internal surface area of the evaporator casing 230. As another example, the condensation wick 210 may extend into the bonded perimeter 250.

The thickness of the condensation wick 210, for example, may be about 0.1 mm, 0.25 mm, 0.4 mm, etc. As another example, the thickness of the condensation wick 210 may be about 0.01 mm to about 1.0 cm. The thickness of the condensation wick 210, for example, may be nonuniform such that the thickness may vary from about 0.01 mm to about 1.0 cm.

The thickness of the condensation wick 210, for example, may be such that it fills substantially all, a majority of, or portions of the internal cavity formed between the evaporator casing 230 and the condenser casing 225.

The condensation wick 210 and the evaporation wick 205 together may fill substantially all, a majority of, or portions of the internal cavity formed between the evaporator casing 230 and the condenser casing 225.

A plurality of support structures 215 may be disposed between the evaporation wick 205 and the condensation wick 210. The plurality of support structures 215, for example, may be bonded or in contact with the evaporation wick 205 and the condensation wick 210. The condensation wick 210 and/or the plurality of support structures 215 may include any or all the features or characteristics described in this document relative to the wick 120.

The support structures 215, for example, may include an array of solid copper posts.

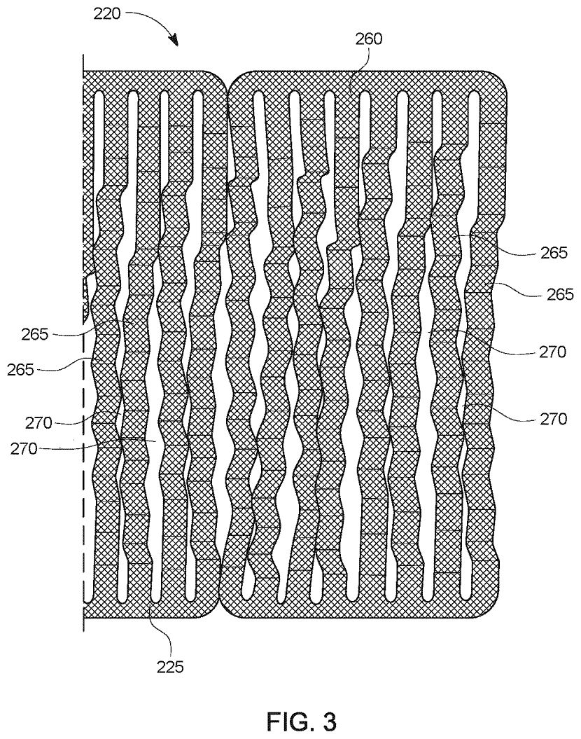

A liquid feed structure 220 may be disposed in certain portions (e.g., the heating regions) of the thermal ground plane 200 between the evaporator casing 230 and condenser casing 225. The liquid feed structure 220 may include the liquid feed structure 220 shown in FIG. 3. The liquid feed structure 220 may allow for liquid transport between the evaporation wick 205 and the condensation wick 210.

The liquid feed structure 220 may be woven or mixed or combined with the plurality of support structures 215. The liquid feed structure 220 may comprise a plurality of strips of a multilayer mesh. The liquid feed structure 220, for example, may be bonded or in contact with either or both the evaporation wick 205 and/or the condensation wick 210. The liquid feed structure 220 may provide vertical and/or horizontal pathways for liquid to flow from the condensation wick 210 to the evaporation wick 205.

The evaporation wick 205, for example, may include a plurality of copper meshes stacked on top of one another. The plurality of meshes, for example, may have different or varied mesh numbers, where a mesh number specifies the number of openings per inch. These mesh may include #100 mesh, #150 mesh, #200 mesh, #250 mesh, #300 mesh, #350 mesh, #400 mesh, #450 mesh, #500 mesh, etc. Alternatively, the evaporation wick 205 may include a plurality of meshes that have the substantially the same mesh number.

The condensation wick 210 for example, may include a plurality of copper meshes stacked on top of one another. The plurality of meshes, for example, may have different or varied mesh numbers, where a mesh number specifies the number of openings per inch. These mesh may include #100 mesh, #150 mesh, #200 mesh, #250 mesh, #300 mesh, #350 mesh, #400 mesh, #450 mesh, #500 mesh, etc. Alternatively, the condensation wick 210 may include a plurality of meshes that have substantially the same mesh number.

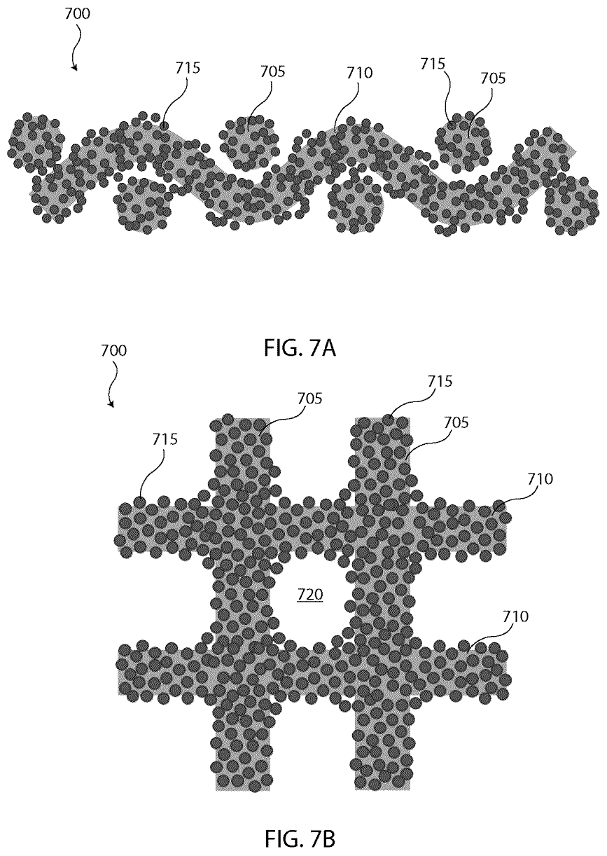

The evaporation wick 205, for example, may comprise a plurality of meshes having the same mesh number or different mesh numbers that are coated with a layer, a single layer, or multiple layers of copper microparticles (e.g., as shown in FIG. 7A and FIG. 7B).

FIG. 3 is an example illustration of a liquid feed structure 220. The liquid feed structure 220, for example, can be formed as single structure having individual feed strips 265 that are connected together along a tie-bar 260 on one or two edges of the liquid feed structure 220. The individual feed strips 265 may have a space 270 between adjacent individual feed strips 265 in either or both the lateral and/or vertical directions. The space 270 between adjacent individual feed strips 265, for example, can have a width of about 1 mm, 2 mm, 5 mm, etc. in either direction. The widths of the space 270 between adjacent individual feed strips 265, for example, may be different in different directions and/or may vary along the length of each individual feed strips 265.

For example, each of the individual feed strips 265 may include a plurality of waves of mesh along a length of each of the individual feed strips 265 (e.g., a wavy structure). These waves, for example, may have a substantially triangular shape. These waves, for example, may have a 4 mm pitch and/or an amplitude of 3 mm.

As another example, adjacent individual feed strips may be spaced about 0.5, 1.0, 1.5, 2.0 mm from each other. As another example, adjacent individual feed strips may be spaced from about 1.0 mm to about 2.0 mm from each other.

The individual feed strips 265 may be connected by a tie-bar 260 at one or both ends to form a single structure. The individual feed strips 265 and/or the tie-bar 260 may be formed from the same structure or mesh. For example, a mesh (or layer of mesh), may be cut or sliced to remove material to create the individual feed strips 265. The mesh may then be crimped or stamped to form the waves.

Adjacent individual feed strips 265 may be formed into waves that are offset relative to each other such that the peaks and valleys of the waves are not aligned for effective liquid transport. For example, adjacent individual feed strips 265 may be offset by about half wavelength. As another example, adjacent individual feed strips 265 may be offset by about a quarter wavelength. Additionally or alternatively, multiple liquid feed structures 220, for example, can be used adjacent to one another with lateral or vertical desired spacing to achieve an optimal liquid flow path geometry. These adjacent liquid feed structures 220 can be assembled floating, formed together, diffusion bonded together, or linked in another way.

The liquid feed structure 220, for example, may comprise a plurality of meshes stacked on top of one another. The plurality of meshes, for example, may have different or varied mesh numbers, where a mesh number specifies the number of openings per inch. These mesh may include #100 mesh, #150 mesh, #200 mesh, #250 mesh, #300 mesh, #350 mesh, #400 mesh, #450 mesh, #500 mesh, etc. Alternatively, the liquid feed structure 220 may include a plurality of meshes that have the same mesh number.

The liquid feed structure 220, for example, may comprise material substantially similar to the evaporation wick 205 and/or the condensation wick 210. An example of the material is copper. The liquid feed structure 220, for example, may be bent out-of-plane compared with the evaporation wick 205.

The individual feed strips 265, for example, may feature a periodic wave shape which may have a wavelength of 1 mm, 2 mm, 4 mm. The liquid feed structure 220, for example, may have a wavelength of about 0.5 mm to 20 mm. The wavelength of adjacent plurality of individual feed strips may be uniform or non-uniform.

The liquid feed structure 220, for example, may be formed in a circular or triangular or spiral (or spring-like) shape. The liquid feed structure 220, for example, may have side lengths or diameters that may be 4 mm, 6 mm, 10 mm, or may range from about 2 mm to about 100 mm. The thickness of the liquid feed structure 220, for example, may have a thickness of about 0.3 mm, about 0.5 mm, etc. The thickness of the liquid feed structure 220, for example, may have a thickness from about 0.05 mm to about 3 mm. The thickness of the liquid feed structure 220, for example, may have a thickness greater than about 3 mm. The thickness of the liquid feed structures 220, for example, may be uniform or nonuniform.

The liquid feed structure 220, for example, may comprise three or more layers of mesh bonded together, which may include outer mesh layers and inner mesh layers. The outer mesh layers, for example, may be in contact with the evaporation wick 205 and/or the condensation wick 210. The inner mesh layers, for example, may only be in contact with other liquid feed structures including the outer liquid feed structures.

In some embodiments, the inner mesh layers may have one or more cut-out regions that form an internal cavity that may be filled with liquid. These one or more cut-out regions may be enclosed on all sides by other wick structures, which may include one of the two outer mesh layers. Such cut-outs, for example, can increase the permeability of liquid flow through the liquid feed structure. In some embodiments, the cut-out regions, for example, may extend through the entire liquid feed structure. In other embodiments, the cut-out regions, for example, may extend from the condensation wick 210 to a region near the evaporation wick 205. These cut-out regions, for example, may not extend over the evaporator wick. Instead, for example, these cut-out regions may end a distance from the evaporator of about 0.1 mm, 0.5 mm, 1 mm, etc.

The thermal ground plane 200, for example, can transport heat from a heat source to a cold plate or heat sink. One or more heat sources, for example, can be placed anywhere on the surface of the evaporation wick 205. The locations of the one or more heat sources can be changed from one application to another or during the operation or use of the thermal ground plane 200.

As another example, the liquid feed structure 220 may include plurality of layers of mesh bonded together. The plurality of layers of mesh can be substantially similar to each other For example, three layers of mesh may be included with each layer having the same mesh number (e.g., #145). As another example, the plurality of layers of mesh may have different mesh numbers: a first mesh with a mesh number of #400 can be bonded to mesh with a mesh number of #200, which can be bonded to another mesh with a mesh number of #400. Small pores in the mesh (e.g., with a mesh number of #200, #250, #300, or #400), for example, can prevent vapor penetration into the flow channel formed by the #200 mesh in liquid feed structure 220.

The condensation wick 210 may be bonded with the condenser casing 225, for example, to maintain structure integrity under pressure difference between the vapor pressure inside the thermal ground plane and ambient pressure outside the thermal ground plane. The evaporation wick 205 may be bonded with the evaporator casing 230, for example, to maintain structure integrity under pressure difference between the vapor pressure inside the thermal ground plane and ambient pressure outside the thermal ground plane. The plurality of support structures 215 may be bonded with the condensation wick 210 and/or the evaporation wick 205, for example, to maintain structure integrity under pressure difference between the vapor pressure inside the thermal ground plane and ambient pressure outside the thermal ground plane.

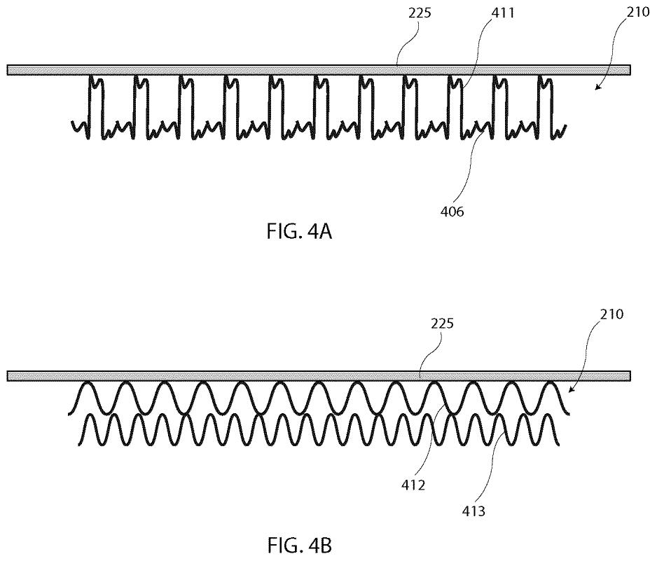

FIG. 4A illustrates a side view of a condensation wick 210 with a plurality of pillars 411. The plurality of pillars 411 may, for example, have a uniform or nonuniform height of about 0.1 mm, 0.2 mm, etc. The plurality of pillars 411 may, for example, have a height from about 0.05 mm to about 0.5 mm. The plurality of pillars 411 may, for example, have a height that is greater than about 0.5 mm. The plurality of pillars 411, for example, may have a pitch of about 0.15 mm, 0.3 mm, 0.6 mm. The plurality of pillars 411, for example, may have a pitch in the range of about 0.1 mm to about 1 mm or larger.

The mesh layer 406 may have a thickness between about 0.01 mm and about 0.1 mm. The mesh layer 406, for example, may or may not cover the entirety of the plurality of pillars 411.

FIG. 4B illustrates a side view of an example condensation wick 210 comprising a multiple layer mesh with each layer having different pore sizes. For example, the condensation wick 210 may include a first mesh 412, which is bonded with the condenser casing 225, and a second mesh 413. The first mesh 412 may be bonded with the second mesh 413. The first mesh 412 may have a larger pore size than the second mesh 413. For example, the first mesh 412 may be a mesh with a pore size corresponding to #100 and the second mesh 413 may be a mesh with a pore size corresponding to #200. The finer mesh (smaller pore size) may assure effective condensation, while the second mesh 413 may have a coarser mesh (larger pore size) coupled with the condenser casing 225 to provide an effective fluid channel for the condensed liquid flow. Such a multilayer mesh, for example, can provide effective condensation and liquid flow.

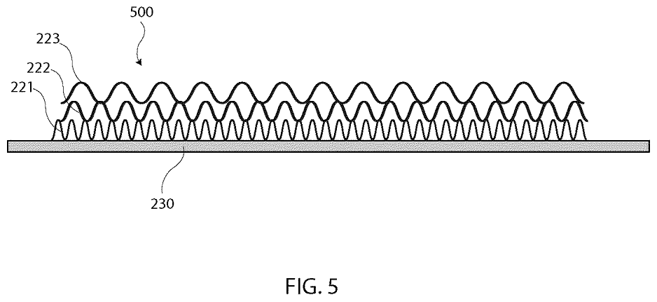

FIG. 5 is an example illustration of a sideview of a multilayer mesh 500. The multilayer mesh 500, for example, may be used as an evaporation wick such as, for example, the multilayer mesh 500. The multilayer mesh 500, for example, may be bonded to the evaporator casing 230. The multilayer mesh 500 may include a plurality of mesh layers. In this example, the multilayer mesh 500 includes a first mesh 221, a second mesh 222, and a third mesh 223. In one example, the plurality of mesh layers may have different pore sizes. For example, the first mesh 221 may have a pore size of #400, the second mesh 222 may have a pore size of #200, and the third mesh 223 may have a pore size of #100. The mesh with the highest pore size may, for example, be bonded with the evaporator casing 230. Such a multilayer mesh, for example, can provide effective evaporation and fluid flow. As another example, each of the plurality of mesh layers may have substantially similar pore sizes.

The multilayer mesh 500, for example, may have a thickness of about 0.3 mm. The multilayer mesh 500, for example, may have a thickness ranging from about 0.1 mm to about 1 mm. The multilayer mesh 500, for example, may have a thickness that is uniform or non-uniform.

The plurality of support structures 215 may comprise a plurality of structures or a unitary structure. The plurality of support structures 215 may have features that are periodically arranged about the plurality of support structures 215. The features of the support structures 215, for example, may have a repeating period of about 3 mm, 5 mm, 10 mm. The features of the support structures 215, for example, may have a repeating period in the range of about 0.5 mm to about 15 mm. The features of the support structures 215, for example, may have a repeating period greater than about 15 mm or larger. The thickness of the support structures 215, for example, may be about 1 mm, 2 mm, 4 mm. The thickness of the support structures 215, for example, may be in the range of about 0.5 mm to about 15 mm. The thickness of the support structures 215, for example, may be uniform or nonuniform. The in-plane size of the support structures 215, for example, may extend into the bonded perimeter 250 of the thermal ground plane The in-plane size of the support structures 215, for example, may only be a partial portion of the thermal ground plane. The in-plane size of the support structures 215, for example, may be discontinuous or continuous in their respective in-plane size.

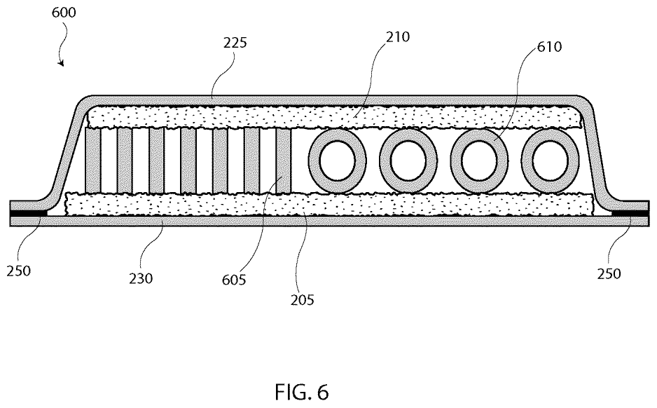

FIG. 6 is a cutaway side view illustration of an example internal structure of a thermal ground plane 600 that includes two types of vapor support structures: hollow beads 610 and/or solid pillars 605 that are disposed between the evaporation wick 205 and the condensation wick 210. Either or both may be used. The solid pillars 605 and/or the hollow beads 610 may be bonded with the evaporation wick 205 and/or the condensation wick 210, for example, to maintain structure integrity under pressure difference between the vapor pressure inside the thermal ground plane and ambient pressure outside the thermal ground plane.

The hollow beads 610, for example, may comprise a porous material with pores having a dimension in micrometers. The hollow beads 610, for example, may have a height between about 1 mm and about 10 mm. The hollow beads 610, for example, may have a height greater than about 10 mm.

The hollow beads 610, for example, may have a height between about 1 mm and about 10 mm. The solid pillars 605, for example, may have a height greater than about 10 mm. The solid pillars 605, for example, may comprise a porous material with pores having a dimension in micrometers.

A vapor support structure and liquid feed structure, for example, can be integrated with the casings as shown in FIG. 2A and FIG. 2B. A vapor support structure and liquid feed structure, for example, can be deformable to accommodate different electronic device heights. For high heat flux applications, the electronic device must make effective thermal contacts with a thermal interface material between the electronic device and the thermal ground plane. The contact pressure level required is very high. Corresponding to such a high pressure level of each electronic device, there is an embodiment that deforms the casing/mesh locally. Such local deformations can accommodate different electronic device heights.

In some embodiments, the internal structures of the high heat flux thermal ground plane include micro-or nano-texturing. This texturing can be formed by oxidizing metal, by de-alloying brass into porous copper, by deposition of ceramic by atomic layer deposition, etc.

FIG. 7A illustrates a side view of some threads of a portion of a mesh structure 700 and FIG. 7B illustrates a top view of some threads of the portion of a mesh structure 700. In this example, the mesh comprises a plurality of threads that are woven together with a pattern having a plurality of holes. The threads may comprise metallic wires such as, for example, cooper wires, stainless steel wires, etc.

In FIG. 7A and FIG. 7B, longitudinal threads 710 are woven with latitudinal threads 705 to form the mesh structure 700. The woven threads create a mesh structure 700 with a plurality of holes 720. The density of these holes (holes per inch) is considered the mesh number.

In this example, a plurality of microparticles 715 are substantially uniformly deposited on the latitudinal threads 705 and the longitudinal threads 710. These plurality of microparticles 715 may be deposited throughout all or portions of the mesh structure 700. The average diameter of the plurality of microparticles 715, for example, can range from about 1 micron to about 5 microns. The plurality of microparticles 715, for example, may be deposited in a substantially single layer. The plurality of microparticles 715, for example, may form a layer that is substantially as thin as the average microparticle diameter. The plurality of microparticles 715, for example, may form a layer that is thinner than twice a microparticle diameter. The plurality of microparticles 715, for example, may form a layer where more than 90% or 95% of the layer comprises a single layer of microparticles. The plurality of microparticles 715, as another example, may be deposited in a multiple layers. The deposition can occur on a mesh that comprises a plurality of mesh layers. A deposition of microparticles, for example, can enhance the wicking properties of the mesh to increase capillary pumping pressure without blocking the vapor and liquid flows.

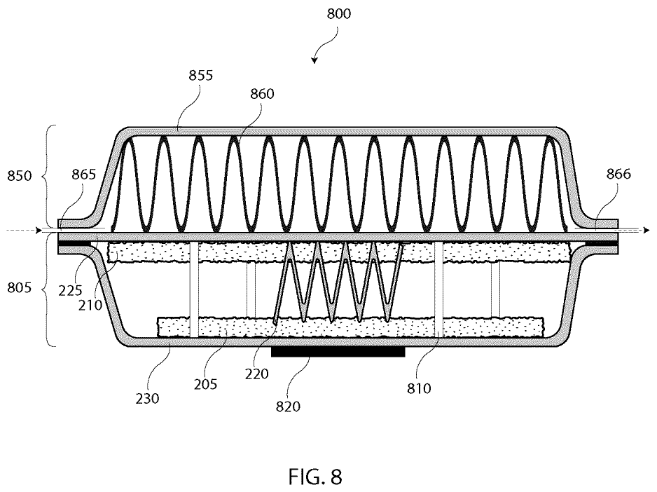

FIG. 8 is a cutaway side view illustration of an example internal structure of an integrated thermal ground plane 800 with a cold plate cold plate 850 combined with a thermal ground plane 805. The thermal ground plane 805 may include any or all the components of thermal ground planes described in this document or any of the priority documents in any combination. The condenser casing 225 of the thermal ground plane 805, which is where a condenser might typically be located, is also the bottom casing for the cold casing 850, which also includes top casing 855. Together the condenser casing 225 and the top casing can be sealed together to create the cold plate. Cooling liquid may flow through the cold plate 850 from the inlet 865 to the outlet 866 to enhance heat transfer from condenser casing 225 (or condenser) into the cooling liquid as it flows through the cold plate 850. The cold plate 850, for example, may include fins, meshes, channels, and/or other features used in cold plates. These features inside the cold plate may or may not be bonded to either or both the condenser casing 225 and/or the evaporator casing 230.

In a typical configuration where the thermal ground plane 805 and the cold plate 850 are not integral, a thermal interface material is disposed between the casing of the condenser (e.g., condenser casing 225) of the thermal ground plane and a casing of a cold plate. The elimination of this interface with a shared casing can enhance thermal performance without a demand on the planarity and/or flatness of the casings and the integrity of the thermal interface material. In addition, this may allow the integrated thermal ground plane 800 to be flexible, foldable, and/or deformable. This may also allow for various three-dimensional configurations that maintain a reliable thermal efficiency.

The condenser casing 225, for example, may comprise aluminum, stainless steel, polymer coated with metal, flexible copper clad laminate (FCCL), or ceramic materials. The evaporator casing 230, for example, may comprise aluminum, stainless steel, polymer coated with metal, flexible copper clad laminate (FCCL), or ceramic materials.

The cold plate 850, for example, may include one or more support structures 860. The thermal ground plane 805 for example, may include one or more support structures 810.

A typical cold plate may suffer from any number of problems. Hot spots corresponding to abnormally high heat flux cannot be removed effectively by a cold plate. The effective heat transfer coefficients on a cold plate can also vary a lot when the liquid flows are not distributed according to the design. With a thermal ground plane integrated with a cold plate, the hot spots are removed by the thermal ground plane, which remains near isothermal with varying heat transfer coefficients along the cold plate. These two problems can be solved with an integrated thermal ground plane and cold plate.

In one specific example, the condenser casing 225 and/or the evaporator casing 230 may comprise a flexible copper clad laminate (FCCL). Because FCCL is flexible and does not have a flat surface, it is challenging to properly attach a FCCL-based thermal ground plane to a FCCL-based cold plate if they are two separate components with a good thermal interface. The integrated thermal ground plane 800 may overcome these problems.

The evaporator casing 230 may comprise a flexible copper clad laminate (FCCL). A typical FCCL includes three layers: copper, polymide, and copper where the polymide is the middle layer. Portions of the outer copper and polymide layers of the evaporator casing 230 may be removed to form cutouts (e.g., a window). These cutouts may be sized and located so that when the thermal ground plane 200 is placed on a circuit board, these cutouts may be aligned with the one or more chip 820 and may reduce thermal resistance across the polymide layer.

Additionally or alternatively, a plurality of thermal vias may be located within the evaporator casing 230 and may be sized and located so that when the thermal ground plane 200 is placed on a circuit board, these thermal vias may be aligned with the one or more chips 820 and may reduce thermal resistance across the polymide layer.

The top surface of the condenser casing 225 facing the internals of the bonded perimeter 250, for example, may have all or portions of the top copper and middle polymide layers removed to reduce thermal resistance. Additionally or alternatively, a plurality of thermal vias, for example, may be located through the condenser casing 225.

A copper, stainless steel, nickel, ceramic, or glass pedestal, for example, can be coupled with evaporator casing 230 including an evaporation wick 205 comprising a FCCL.

The evaporator casing 230 and condenser casing 225, may be hermetically sealed around the outer peripheries of each of these casings. The casings can be hermetically sealed, for example, using high temperature, low temperature diffusion bonding, laser welding, ultrasonic welding, soldering, brazing processes, etc.

The flexible integrated thermal ground plane and cold plate can be attached to or coupled with the one or more chips 820 with different heights. The flexibility accommodates the height variations for excellent gap control of thermal interface material between the thermal ground plane's evaporator region and the one or more chips 820.

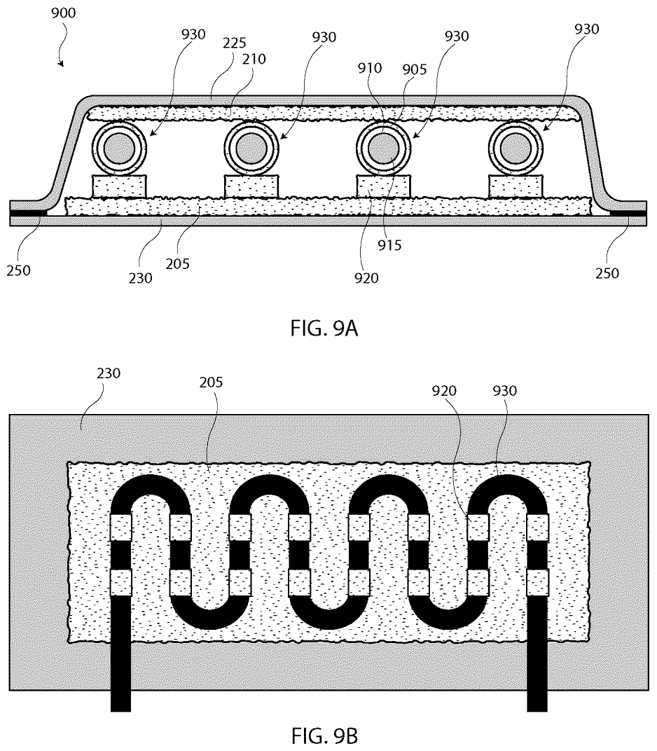

FIG. 9A is cutaway side view of an integrated thermal ground plane 900 with a plurality of cooling pipes 930. And FIG. 9B is a top view of the integrated thermal ground plane 900. The plurality of cooling pipes 930 are cooling pipes that may be a single pipe that is wrapped around the interior of the integrated thermal ground plane 900 or may be a plurality of pipes within the integrated thermal ground plane 900. The plurality of cooling pipes 930 can conduct cooling liquid through the interior of the integrated thermal ground plane 900. The plurality of cooling pipes 930 may server as a condenser.

Each of the plurality of cooling pipes 930 may include an interior channel 915 through which cooling liquid may be conducted and a cooling pipe wall 910. Each of the plurality of cooling pipes 930 may include a condenser wick 905 on the exterior of the cooling pipe wall 910. This condenser wick 905 may comprise any of the wick or mesh materials disclosed in this document or any of the priority documents.

The plurality of cooling pipes 930 may be disposed on a liquid feed wick 920 that is in contact with the evaporation wick 205. The liquid feed wick 920, for example, may include a plurality of pillars.

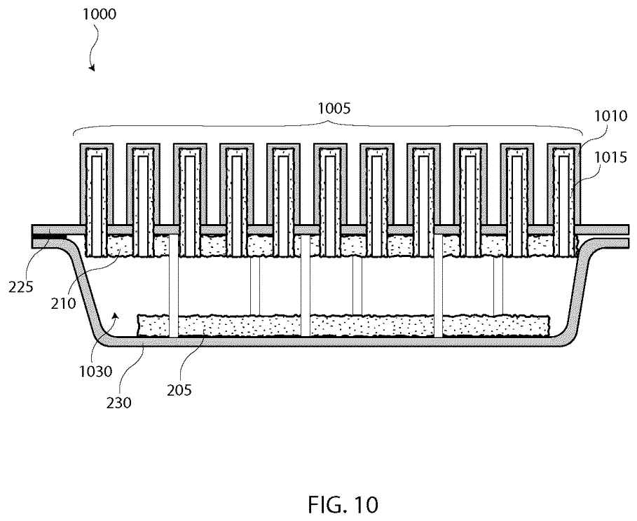

FIG. 10 is cutaway side view of an integrated thermal ground plane 1000 with a plurality of external fins 1005. These external fins 1005 can also be used to connect to one or more external heat sinks. Each of the plurality of external fins 1005, for example, may include a casing 1010 and condenser wicks 1015 may be disposed within the plurality of external fins 1005 for air cooling. The thermal conductivities of the plurality of external fins 1005 may affect the thermal performance of an air-cooled heat sink. The plurality of external fins 1005 with vapor condensed to liquid inside may be more thermally effective than solid copper, aluminum, or other high thermal conductivity materials.

The condenser wicks 1015, for example, may extend inwardly into the cavity 1030 of the integrated thermal ground plane 1000. This will increase the surface area of the condenser wicks 1015, which may, for example, increase condensation performance.

Another embodiment to use the above fins as an integral part of the condenser for liquid cooling. The heat flux in the condenser region is further reduced with the extended surface. Such a reduction enables the use of air-cooled heat sinks. For liquid cooling, such a reduction also enables the use of simplified liquid cooling.

As another example, a liquid distribution wick may also be included. The liquid distribution wick may be disposed between the condenser wicks 1015 and the condensation wick 210. The liquid distribution wick, for example, may be substantially parallel to the evaporation wick 205. The liquid distribution wick, for example, may be in fluidic contact with the condenser wicks 1015. The liquid distribution wick, for example, may include vapor-flow arteries cut-out from the wick body, such that vapor can pass through the cutouts from the vapor core into the condenser wicks 1015. The liquid distribution wick, for example, may form a bridge between the evaporation wick 205 and the condenser wicks 1015.

The cut-outs, for example, may include individual holes of similar size to a single fin. The cut-outs, for example, may span several fins. The cutouts in the liquid distribution wick, for example, may form a periodic structure.

A liquid distribution wick, for example, may be in fluid contact with a liquid feed structure disposed within the cavity of the integrated thermal ground plane 1000. A plurality of cutouts in the liquid distribution wick may run parallel to similar cut-outs in the liquid feed structure. As another example, cutouts in the liquid distribution wick may run perpendicular or skew with cutouts in the liquid feed structure, such that the periodic cutouts in the liquid distribution wick are aligned with the periodic out-of-plane features in the liquid feed structure. As another example, the liquid distribution wick can act as a tie-bar for the liquid feed structure, such that the liquid feed structure is composed of a plurality of disconnected mesh strips with periodic out-of-plane features.

The liquid distribution wick, for example, may comprise a multi-layer mesh structure with thickness of between about 0.05 mm and about 2 mm. The liquid distribution wick, for example, may comprise a multi-layer mesh structure with thickness of about 0.1 mm, 0.3 mm, 0.5 mm, 1 mm, etc.

Another embodiment is to use the above fins to reduce thermal resistance across the middle polymer layer in FCCL-based thermal ground planes. With substantially reduced heat flux resulting from the extended surface, there is an option not to use thermal vias or cut out through the exterior copper and the middle polymer layers.

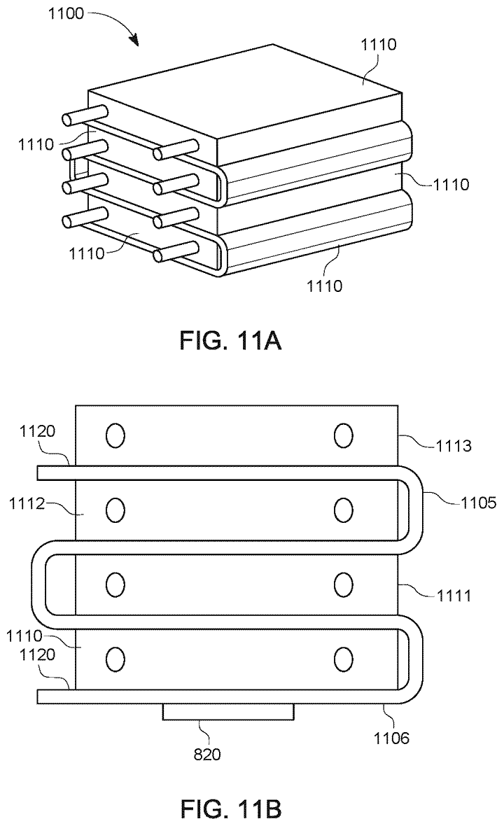

FIG. 11A and FIG. 11B illustrate an example vertically integrated thermal ground plane 1100 that is a folded thermal ground plane 1105 integrated vertically between a plurality of cold plates 1110, 1111, 1112, 1113. The folded thermal ground plane 1105 can be folded multiple times vertically and interposed between cold plates 1110, 1111, 1112, 1113. One surface of the folded thermal ground plane 1105 may be in contact with the one or more chips 820. The folding angles, for example, may range from about 10° to about 180°. The flat portions of the folded thermal ground plane 1105 can be thermally coupled to different surfaces of the plurality of cold plates 1110, 1111, 1112, 1113 through a thermal interface material.

The flat regions of the vertically integrated thermal ground plane 1100 are coupled with both an upper cold plate and a lower cold plate are cooled by cold plates on both sides. In such an example, other than the portion of the folded thermal ground plan 1105 that is in contact with the one or more chips may have wicks that serve as condensers. The thermal performance of the folded thermal ground plane 1105 integrated vertically with a plurality of cold plates 1110, 1111, 1112, 1113 may be enhanced substantially.

Each of the plurality of cold plates 1110, 1111, 1112, 1113 may be coupled with liquid that is pumped or flowed through the plurality of cold plates 1110, 1111, 1112, 1113.

In another example, the plurality of cold plates 1110, 1111, 1112, 1113 can be replaced with one or more heat sinks or air-cooled cold plates.

The one or more chips 820, for example, may be clamped with surface 1106 of the folded thermal ground plane 1105. For example, loading can be applied to the cold plate 1110 outside the thermal interface material 1120 between the flat region of the folded thermal ground plane 1105 and the cold plate 1110. The outside region, for example, can be along the out-of-plane direction.

As another example, the cold plate 1110 may not be flush with the TGP as shown in FIG. 11A. The cold plate 1110 can have two ends extended as protrusions outside the TGP region that can be pressed against a motherboard for clamping the vertically integrated thermal ground plane 1100 to one or more chips on a circuit board.

The vertically integrated thermal ground plane 1100 can reduce the footprint of the cooling unit. The vertically integrated thermal ground plane 1100, for example, may have a thickness of about 2 mm, 4 mm, 10 mm, 20 mm, 40 mm, 100 mm, etc.

The folded thermal ground plane 1105, for example, may comprise any kind of thermal ground planes such as, for example, the integrated thermal ground plane 800 and/or the thermal ground plane 200. If the folded thermal ground plane 1105 comprises the integrated thermal ground plane 800 may not need a thermal interface material 1120.

The folded thermal ground plane 1105, for example, can be folded around portions of the first cold plate 1111 to substantially conform to the physical shape of the first cold plate 1111. The condenser casing 225, the evaporator casing 230, the evaporation wick 205, the condensation wick 210 and/or the liquid feed structure 220 may also have a shape that conforms to the shape of the physical shape of the first cold plate 1111.

The folded thermal ground plane 1105, for example, can be folded around portions of the second cold plate 1112 to substantially conform to the physical shape of the second cold plate 1112. The condenser casing 225, the evaporator casing 230, the evaporation wick 205, the condensation wick 210 and/or the liquid feed structure 220 may also have a shape that conforms to the shape of the physical shape of the second cold plate 1112.

The folded thermal ground plane 1105, for example, can be folded around portions of the third cold plate 1113 to substantially conform to the physical shape of the third cold plate 1113. The condenser casing 225, the evaporator casing 230, the evaporation wick 205, the condensation wick 210 and/or the liquid feed structure 220 may also have a shape that conforms to the shape of the physical shape of the third cold plate 1113.

The folded thermal ground plane 1105, for example, can be folded around portions of the fourth cold plate 1114 to substantially conform to the physical shape of the fourth cold plate 1114. The condenser casing 225, the evaporator casing 230, the evaporation wick 205, the condensation wick 210 and/or the liquid feed structure 220 may also have a shape that conforms to the shape of the physical shape of the fourth cold plate 1114.

The various examples or embodiments discussing a liquid-cooled cold plate, the liquid-cooled cold plate may be replaced with any other type of thermal management system such as, for example, an air-cooled thermal management.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

While the present subject matter has been described in detail with respect to specific examples thereof, it will be appreciated that those skilled in the art, upon attaining an understanding of the foregoing, may readily produce alterations to, variations of, and equivalents to such examples. Accordingly, the present disclosure has been presented for purposes of example rather than limitation, and does not preclude inclusion of such modifications, variations and/or additions to the present subject matter as would be readily apparent to one of ordinary skill in the art.

That which is claimed:

1. A thermal ground plane comprising:
a first casing;
a first wick bonded with the first casing, the first wick is configured for liquid transport associated with evaporation or boiling;
a second casing, wherein the outer periphery of the first casing and the outer periphery of the second casing are bonded to each other with a hermetic seal and forms an internal cavity;
a second wick disposed within the internal cavity and bonded with the second casing, the second wick is configured for liquid transport associated with condensation;
a liquid feed structure disposed within the internal cavity between the first wick and the second wick, the liquid feed structure allows liquid transport between the first wick and the second wick, the liquid feed structure comprising a plurality of individual feed strips having a space between adjacent individual feed strips and each of the plurality of individual feed strips coupled with a tie-bar;
a working fluid disposed within the internal cavity.

2. The thermal ground plane according to claim 1, wherein each of the plurality of individual feed strips comprise a wavy structure.

3. The thermal ground plane according to claim 2, wherein the wavy structure of adjacent individual feed strips are offset by about half a wavelength relative to one another.

4. The thermal ground plane according to claim 1, wherein liquid feed structure comprises one or more mesh.

5. The thermal ground plane according to claim 1, wherein the space between adjacent individual feed strips is less than about 1.5 mm.

6. The thermal ground plane according to claim 1, wherein either or both the first wick and/or the second wick comprise a mesh coated with a layer of microparticles.

7. The thermal ground plane according to claim 6, wherein the layer of microparticles comprises a thickness less than one and a half the diameter of the average microparticle.

8. The thermal ground plane according to claim 6, wherein more than 90% of the layer of microparticles comprises a single layer of microparticles.

9. The thermal ground plane according to claim 6, wherein the microparticles comprising the layer of microparticles have an average diameter less than about 5 microns.

10. A thermal ground plane comprising:
a first casing;
a second casing, wherein the outer periphery of the first casing and the outer periphery of the second casing are bonded to each other with a hermetic seal and forms an internal cavity;
a first wick disposed within the internal cavity and bonded with the first casing, the first wick is configured for liquid transport associated with evaporation or boiling;
a second wick disposed within the internal cavity and bonded with the second casing, the second wick is configured for liquid transport associated with condensation;
a working fluid disposed within the internal cavity; and
a liquid-cooled cold plate where the second casing is part of the liquid-cooled cold plate.

11. The thermal ground plane according to claim 10, wherein liquid flows through the liquid-cooled cold plate and the liquid is in contact with a portion of the second casing.

12. The thermal ground plane according to claim 10, wherein there is no thermal interface material disposed between the liquid-cooled cold plate and the second casing.

13. The thermal ground plane according to claim 10, wherein the liquid-cooled cold plate comprises a third casing, wherein the outer periphery of the second casing is bonded with an outer periphery of the third casing to form a hermetic seal and allows liquid to flow between the second casing and the third casing.

14. The thermal ground plane according to claim 10, wherein the second casing comprises a plurality of layers including a polymer layer.

15. The thermal ground plane according to claim 10, wherein the liquid-cooled cold plate is folded.

16. A thermal ground plane comprising:
a first casing;
a second casing comprising a plurality of fins that extend out of plane from an external surface of the second casing, wherein the outer periphery of the first casing and the outer periphery of the second casing are bonded to each other with a hermetic seal and forms an internal cavity;
a first wick disposed within the internal cavity and bonded with the first casing, the first wick is configured for liquid transport associated with evaporation or boiling;
a second wick disposed within the internal cavity and bonded with the second casing, the second wick is configured for liquid transport associated with condensation; and
a working fluid disposed within the internal cavity.

17. The thermal ground plane according to claim 16, wherein the second wick extends into at least a subset of the plurality of fins.

18. A cooling system comprising:
a first cold plate having a first physical shape and a liquid-cooling channel; and
a thermal ground plane having a second physical shape that is folded around portions of the cold plate to substantially conform to a portion of the first physical shape, wherein the thermal ground plane comprises
a first casing having a shape that substantially conforms with the second physical shape;
a second casing having a shape that substantially conforms with the second physical shape, the second casing is in contact with two or more surfaces of the first cold plate, wherein the outer periphery of the first casing and the outer periphery of the second casing are bonded to each other with a hermetic seal and forms an internal cavity;
a first wick configured for liquid transport associated with evaporation or boiling, the first wick disposed within the internal cavity and bonded with the first casing;
a second wick configured for liquid transport associated with both condensation and evaporation, the second wick disposed within the internal cavity and bonded with the second casing; and
a working fluid disposed within the internal cavity.

19. The cooling system according to claim 18, wherein the internal cavity is maintained through folds of the thermal ground plane.

20. The cooling system according to claim 18, wherein the first wick has a shape that substantially conforms with the second physical shape, and wherein the second wick has a shape that substantially conforms with the second physical shape.

21. The cooling system according to claim 18, further comprising a second cold plate with liquid-cooling channels, wherein second portions of the first wick are configured for liquid transport associated with condensation, and wherein the first casing is in contact with two or more surfaces of the second cold plate.

22. The cooling system according to claim 18, further comprising a third cold plate with liquid-cooling channels, wherein the second casing is in contact with one or more surfaces of the third cold plate.

23. The cooling system according to claim 18, wherein the second casing comprises a polymer layer.
